(19) United States
(12) Patent Application Publication
(10) Pub. No.: US 2025/0218908 A1
(43) Pub. Date: Jul. 3, 2025

(54) MULTI-DIE TRANSFORMER POWER MODULES

(71) Applicant: TEXAS INSTRUMENTS INCORPORATED, Dallas, TX (US)

(72) Inventors: Giacomo CALABRESE, Freising (DE); Yasmine YAN, San Jose, CA (US); Suvadip BANERJEE, Bangalore (IN); Nicola BERTONI, Freising (DE); Dongbin HOU, Plano, TX (US); Pei-Hsin LIU, Bedford, NH (US); Michael LUEDERS, Freising (DE); Hiep NGUYEN, Cedar Hill, TX (US); Kashyap MOHAN, Irving, TX (US)

(21) Appl. No.: 18/397,729

(22) Filed: Dec. 27, 2023

(51) Int. Cl. H01L 23/495; H01L 23/00; H01L 25/065

(52) U.S. Cl. CPC H01L 23/49575; H01L 23/4952; H01L 24/16; H01L 24/48; H01L 25/0652; H01L 2224/16145; H01L 2224/16225; H01L 2224/48155; H01L 2224/48225; H01L 2924/014; H01L 2924/1206; H01L 2924/182

(57) ABSTRACT

In examples, an isolation device comprises a multi-level substrate having opposing first and second surfaces. The multi-level substrate includes a first coil in a first layer of the substrate, the first coil having first and second terminals, a second coil in a second layer of the substrate that is vertically distanced from the first layer, the second coil having third and fourth terminals, and a dielectric material covering the first and second coils. The device comprises a first semiconductor die coupled to the first surface and to the first and second terminals, a second semiconductor die coupled to the second surface and to the third and fourth terminals, the second semiconductor die galvanically isolated from the first semiconductor die, conductive terminals coupled to the multi-level substrate, and a mold compound covering the multi-level substrate, the first and second semiconductor dies, and the conductive terminals.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. Dies are then coupled to a lead frame and are covered by a mold compound, which is subsequently sawn to produce a package.

### SUMMARY

In examples, an isolation device comprises a multi-level substrate having opposing first and second surfaces. The multi-level substrate includes a first coil in a first layer of the substrate, the first coil having first and second terminals, a second coil in a second layer of the substrate that is vertically distanced from the first layer, the second coil having third and fourth terminals, and a dielectric material covering the first and second coils. The device comprises a first semiconductor die coupled to the first surface and to the first and second terminals, a second semiconductor die coupled to the second surface and to the third and fourth terminals, the second semiconductor die galvanically isolated from the first semiconductor die, conductive terminals coupled to the multi-level substrate, and a mold compound covering the multi-level substrate, the first and second semiconductor dies, and the conductive terminals.

In examples, a method for manufacturing an isolation device comprises coupling a first semiconductor die to a first coil of a multi-layer substrate using first solder bumps, the substrate including a second coil and a dielectric material covering the first and second coils; coupling the substrate to conductive terminals of a lead frame; coupling a second semiconductor die to the second coil using second solder bumps, the first and second semiconductor dies coupled to opposing surfaces of the substrate; covering the substrate and the first and second semiconductor dies with a mold compound; and trimming the conductive terminals to detach the conductive terminals from the lead frame.

### BRIEF DESCRIPTION OF THE DRAWINGS

FIG. 1A is a profile, cross-sectional view of an isolation device in accordance with various examples.

FIG. 1B is a top-down view of an isolation device in accordance with various examples.

FIG. 1C is a perspective view of an isolation device in accordance with various examples.

FIG. 2A is a profile, cross-sectional view of an isolation device in accordance with various examples.

FIG. 2B is a top-down view of an isolation device in accordance with various examples.

FIG. 2C is a perspective view of an isolation device in accordance with various examples.

FIG. 3 is a flow diagram of a method for manufacturing an isolation device in accordance with various examples.

FIGS. 4A1-4F3 are a process flow for manufacturing an isolation device in accordance with various examples.

FIGS. 5A and 5B are top-down views of isolation device substrate coils indicating temperature, in accordance with various examples.

FIG. 6A is a graph depicting the operational behavior of isolation devices in accordance with various examples.

FIGS. 6B and 6C depict representative isolation devices that may behave as depicted by the curves of the graph in FIG. 6A.

### DETAILED DESCRIPTION

Some isolation devices contain laminate transformers and, optionally, semiconductor dies coupled to the transformers. Some isolation devices include multiple, co-planar die pads, with a first die pad coupled to a transformer, a second die pad coupled to a semiconductor die, and a third die pad coupled to a different semiconductor die. Some isolation devices include multiple, co-planar semiconductor dies coupled to a top surface of the transformer. Some isolation devices include transformer coils that are wire bonded directly to bond pads or leads of the isolation device. These isolation devices suffer from numerous technical disadvantages. For example, the dies and transformers in these configurations are unable to adequately dissipate the heat typically generated in power applications. In addition, in some of the isolation devices described above, bond wires are used to couple dies to the transformer. These bond wires inherently introduce parasitics into the isolation device, and because the bond wires are coupled in series with the coils of the transformer, the bond wires introduce inductive asymmetry and leakage in series with the magnetic components into the isolation device, which can adversely impact isolation device operation. Thus, engineers must account for such bond wire parasitics in the design stage, which presents a substantial technical challenge because of the limited modeling capabilities at the design stage and added design margins which must be considered. In some of the isolation devices described above, to comply with spatial design restrictions, the semiconductor dies must be spaced closely. When a voltage potential exists between the dies, especially in galvanic isolation applications, this proximity between the dies forms a high electric field region between the dies, which can adversely impact isolation device operation and galvanic isolation capability. In addition, in isolation devices where the semiconductor dies are coupled to the same side of the transformer, the transformer must be specifically designed to provide coil terminals to respective semiconductor dies, which can prove to be spatially challenging when fewer transformer coil layers are desired. Isolation devices devised to address such problems suffer from their own challenges. For example, isolation devices designed to minimize the number of transformer layers suffer from strict limits on the number of possible transformer coil turns.

This disclosure describes various examples of an isolation device that mitigates the various technical challenges described above. In examples, an isolation device comprises a multi-level substrate having opposing first and second surfaces. The multi-level substrate includes a first coil in a first layer of the substrate. The first coil has first and second terminals. A second coil in a second layer of the substrate is vertically distanced from the first layer. The second coil has third and fourth terminals. The substrate also includes an insulative material covering the first and second coils. The isolation device comprises a first semiconductor die coupled to the first surface and to the first and second terminals, a second semiconductor die coupled to the second surface and to the third and fourth terminals, conductive terminals coupled to the multi-level substrate, and a mold compound. The mold compound covers the multi-level substrate, the first and second semiconductor dies, and the conductive terminals. Such isolation devices are technically advantageous for several reasons. First, because the first and second semiconductor dies are positioned on opposing first and second surfaces of the substrate, they facilitate heat dissipation from the first and second coils, respectively. Second, the electric fields that are generated between semiconductor dies on the same surface of the substrate, as well as their adverse impact on isolation device operation, are significantly reduced by positioning the first and second dies on opposing surfaces of the substrate. Third, the design challenges associated with connecting coil terminals to dies positioned on the same surface of the substrate are eliminated by positioning the first and second dies on opposing surfaces of the substrate. Fourth, because the first and second semiconductor dies are coupled to their respective terminals by metallic (e.g., solder) bumps instead of bond wires, the disadvantages introduced by the bond wire parasitics as described above are mitigated. Fifth, the isolation device achieves operational symmetry, thus mitigating against the deleterious operational effects of external disturbances acting upon the isolation device. Sixth, because positioning semiconductor dies on opposing surfaces of the multi-layer substrate results in less complex routing of the coils in the substrate (e.g., by eliminating any need for complex coil terminal configurations), fewer layers may be used in the substrate, resulting in a thinner substrate and a thinner isolation device (e.g., up to 50% thinner). Various examples of the isolation device are now described with reference to the drawings.

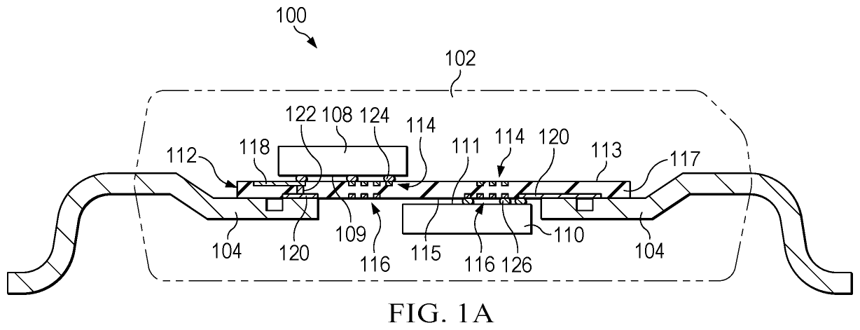

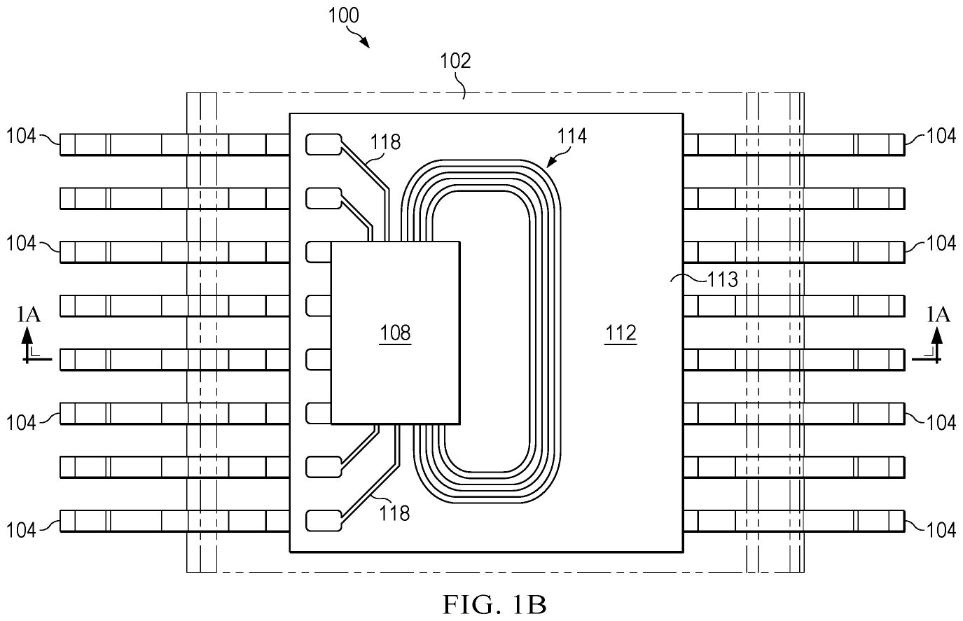

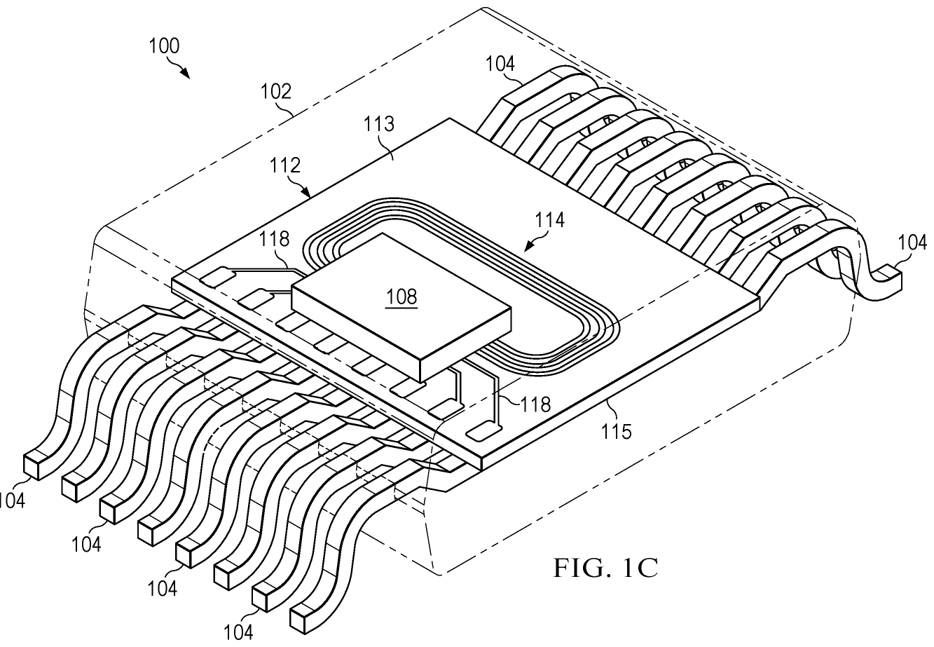

FIG. 1A is a profile, cross-sectional view of an isolation device 100 (e.g., a package) in accordance with various examples. The isolation device 100 may be included in any suitable electronic device or system. For instance, the isolation device 100 may be included in a personal computer, a laptop, a desktop, a notebook, a tablet, a smartphone, an appliance (e.g., refrigerator, television, audio player, video player, video recorder, lighting device, etc.), an automobile, an aircraft, a spacecraft, etc. The isolation device 100 may include a mold compound 102 that covers various structures, including portions of conductive terminals (e.g., leads) 104, a semiconductor die 108 having a device side 109 in which circuitry is formed, and a semiconductor die 110 having a device side 111 in which circuitry is formed. In examples, the semiconductor dies 108, 110 may be galvanically isolated from each other and may operate in different voltage domains. In examples, the semiconductor dies 108, 110 are “flip-chip” coupled to the substrate 112, meaning that the device sides 109, 111 face the substrate 112 and that the isolation device 100 lacks bond wires. The isolation device 100 includes, and the mold compound 102 covers, a multi-layer substrate 112 that has opposing surfaces 113, 115. The surface 113 is coupled to the semiconductor die 108, and the surface 115 is coupled to the semiconductor die 110. In some examples, the semiconductor dies 108, 110 are vertically overlapping, meaning a vertical line that is orthogonal to the surfaces 113, 115 of the substrate 112 extends through both of the semiconductor dies 108, 110. In other examples, the semiconductor dies 108, 110 do not vertically overlap, meaning that no vertical line that is orthogonal to the surfaces 113, 115 of the substrate 112 extends through both of the semiconductor dies 108, 110. The semiconductor dies 108, 110 are vertically separated by a distance that ranges from 100 microns to 500 microns, with a distance lower than this range being disadvantageous because the material composition of the substrate 112 will limit the dielectric strength of the isolation barrier, the mechanical stability of the substrate 112, and the parasitic barrier capacitance, and with a distance above this range being disadvantageous because of reduced coupling between the coils of the transformer for coil sizes that are able to be integrated into the isolation device 100. However, this distance is dependent on the breakdown voltage capability of the material of which the substrate 112 is composed. For example, a silicon dioxide substrate 112 may have a thickness of 15-20 microns, depending on the working voltage intended to be used. This distance increases for organic substrates that have a lower dielectric strength and, thus, lower breakdown voltages.

In examples, the multi-layer substrate 112 comprises multiple transformer coils 114, 116 positioned in different layers of the substrate 112. In examples, the coil 114 is in a layer of the substrate 112 that is between the surface 113 and the surface 115, and that is between the surface 113 and the layer in which the coil 116 is positioned. Similarly, in examples, the coil 116 is in a layer of the substrate 112 that is between the surface 113 and the surface 115, and that is between the surface 115 and the layer in which the coil 114 is positioned. The coils 114, 116 are composed of any suitable type of metal or metal alloy, such as copper. Any number of coils (i.e., two or greater) may be useful. Each coil 114, 116 may have any suitable number of turns. In examples in which more than two coils are used, each such coil may have any suitable number of turns. In examples, the coil 114 is exposed to the surface 113, and in other examples, the coil 114 is embedded within the substrate 112 such that the coil 114 is not exposed to the surface 113. In examples, the coil 116 is exposed to the surface 115, and in other examples, the coil 116 is embedded within the substrate 112 such that the coil 116 is not exposed to the surface 115. In some examples, the coils 114, 116 are vertically overlapping, as vertical overlap is defined above.

The substrate 112 includes traces 118 that may be horizontally co-planar with the coil 114. The substrate 112 includes traces 120 that may be horizontally co-planar with the coil 116. The traces 120 are coupled to the conductive terminals 104, such as by soldering or any other appropriate coupling technique. The traces 118 may be coupled to the conductive terminals 104 by way of one or more of the traces 120. The traces 118 may be coupled to the traces 120 by way of vias 122. Solder bumps 124 couple the device side 109 of the semiconductor die 108 to terminals of the coil 114 and to the traces 118. Similarly, solder bumps 126 couple the device side 111 of the semiconductor die 110 to terminals of the coil 116 and to at least some of the traces 120. The substrate 112 includes a dielectric material 117 (e.g., a solid, non-air dielectric material, such as AJINOMOTO® build-up film, BT Laminate, or another suitable build-up film) that contacts the metal structures of the substrate 112, such as the coils 114, 116, the traces 118, 120, and the vias 122. In some examples, the conductive terminals 104 are coupled to the surface 115, and in other examples, the conductive terminals 104 are coupled to the surface 113 (by way of metal traces 118 and additional metal traces 118 not expressly shown in FIG. 1A).

A multi-layer substrate is defined as a component of a semiconductor package, where the component includes multiple metal layers formed by plating (e.g., electroplating) and that further includes a dielectric such as a mold compound or film (e.g., AJINOMOTO® build-up film (ABF)) filling spaces between and around the multiple metal layers. A multi-layer substrate differs from a printed circuit board (PCB) because the multi-layer package substrate is within the isolation device 100, whereas the PCB is outside the isolation device 100. The multi-layer substrate includes multiple metal layers that are separated by a solid, tangible dielectric, whereas the PCB may contain multiple layers of printed circuit board that may not be separated by a dielectric material other than air.

In operation, the semiconductor die 108 provides power and/or data to and receives power and/or data from the coil 114. The semiconductor die 110 provides power to and receives power from the coil 116. When energized by the semiconductor die 108, the coil 114 produces a fluctuating magnetic field that induces a voltage in the coil 116 through mutual inductance. Similarly, when energized by the semiconductor die 110, the coil 116 produces a fluctuating magnetic field that induces a voltage in the coil 114 through mutual inductance. The semiconductor dies 108, 110 communicate with devices outside of the isolation device 100 by way of the conductive terminals 104. For example, the isolation device 100 may be coupled to a printed circuit board (PCB) on which one or more other devices are mounted, and the isolation device 100 may communicate with such other devices by way of the conductive terminals 104 and metal traces on the PCB.

Because the semiconductor dies 108, 110 are positioned on opposing surfaces 113, 115, respectively, of the multi-layer substrate 112, numerous technical advantages are realized. First, the positioning of the semiconductor dies 108, 110 facilitates heat dissipation from the coils 114, 116, respectively. Second, minimal or no electric fields are generated between the semiconductor dies 108, 110, and thus any adverse impacts on operation of the isolation device 100 due to such electric fields are mitigated or eliminated. Third, the design challenges associated with connecting coil terminals to dies positioned on the same surface of the substrate are eliminated by positioning the semiconductor dies 108, 110 on opposing surfaces 113, 115 of the substrate 112. Fourth, because the semiconductor dies 108, 110 are coupled to their respective terminals by metallic (e.g., solder) bumps 124, 126 instead of bond wires, the disadvantages introduced by the bond wire parasitics as described above are mitigated.

FIG. 1B is a top-down view of the isolation device 100 of FIG. 1A, in accordance with various examples. FIG. 1C is a perspective view of the isolation device 100 of FIG. 1A, in accordance with various examples.

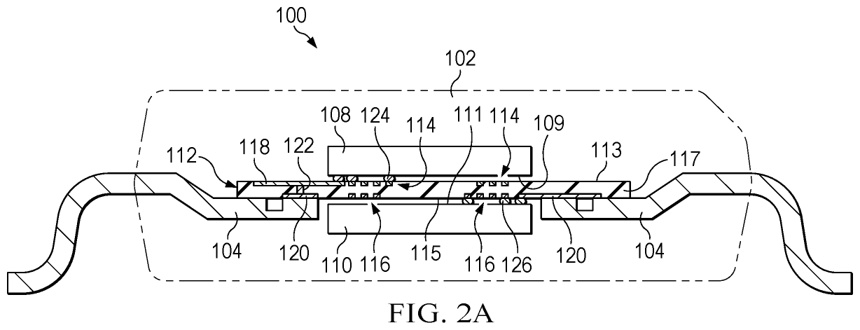

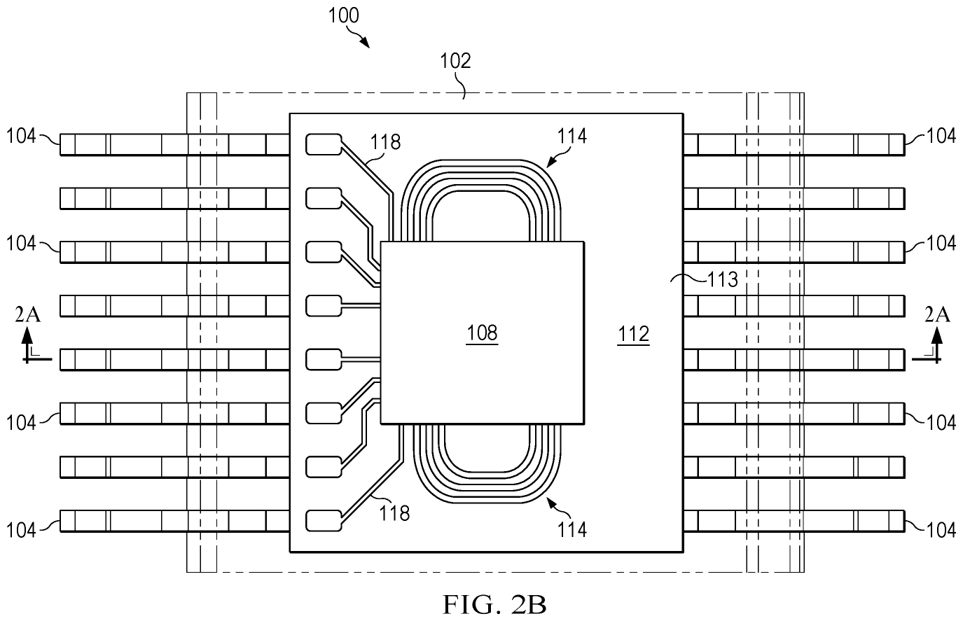

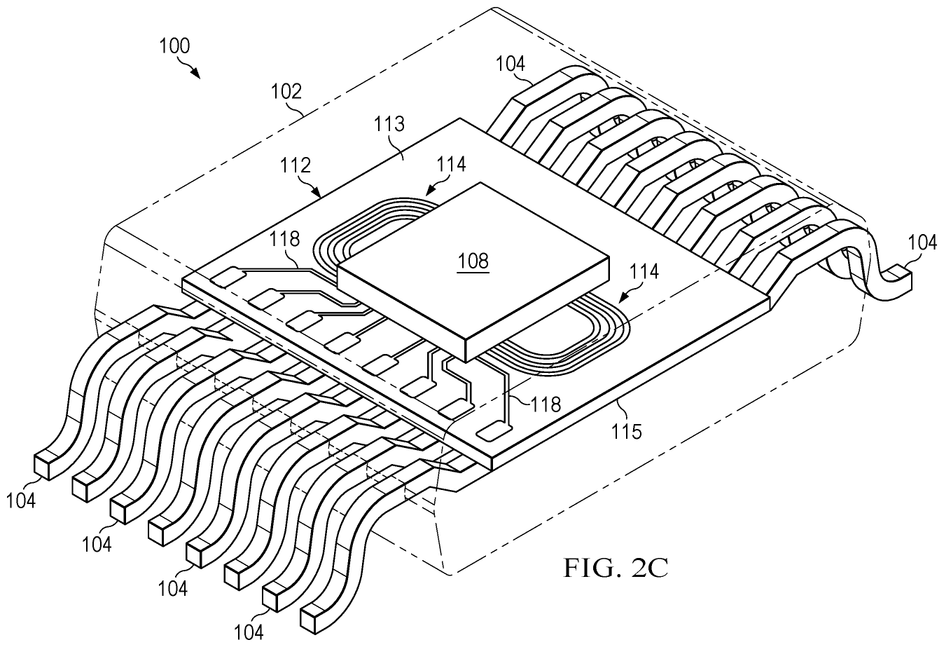

The semiconductor dies 108, 110 may vary in size, position, or both. The positioning of the semiconductor dies 108, 110 on the opposing surfaces 113, 115 of the substrate 112 eliminates any adverse effects that would otherwise result by positioning the semiconductor dies 108, 110 in proximity to each other, such as the formation of electric fields that adversely impact isolation device 100 operation. For example, the semiconductor dies 108, 110 may be centered directly above and below the substrate 112, respectively, as opposed to the configuration of FIG. 1A, in which the semiconductor dies 108, 110 are horizontally offset from each other (i.e., are not centered directly above and below the substrate 112, respectively). The substrate 112 should be adequately thick to form an isolation barrier between the semiconductor dies 108, 110 capable of withstanding the voltages applied. The thickness of the substrate 112 will vary depending on the material used to implement the isolation barrier and the dielectric strength thereof. The thickness of the substrate 112 will also vary depending on the number of routing layers implemented in the substrate 112, which can be any suitable number (e.g., 3-6 layers). Conversely, the substrate 112 should not be excessively thick to avoid unacceptable increases in the size of the isolation device 100, both in vertical thickness and also in substrate 112 area to achieve a suitable coupling between the coils 114, 116. FIG. 2A depicts such semiconductor dies 108, 110 that are centered directly above and below the substrate 112, respectively. Specifically, the isolation device 100 of FIG. 2A is identical to the isolation device 100 of FIG. 1A, except that the semiconductor dies 108, 110 are larger and are centered directly above and below the substrate 112, respectively, as shown. Despite this proximity of the semiconductor dies 108, 110 to each other, the vertical separation between the dies 108, 110 guarantees a certain voltage rating capability between the coils 114, 116. FIG. 2B is a top-down view of the isolation device 100 of FIG. 2A, in accordance with various examples. Further, FIG. 2C is a perspective view of the isolation device 100 of FIG. 2A, in accordance with various examples.

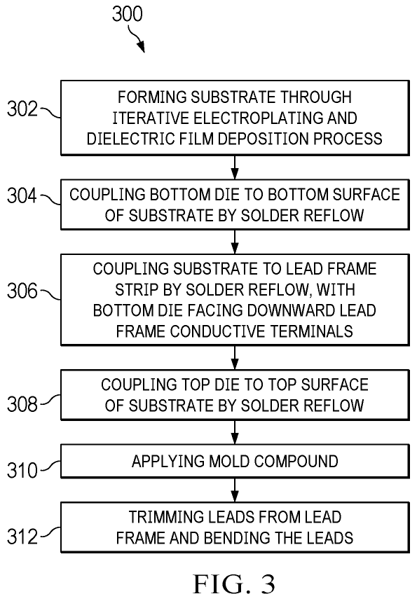

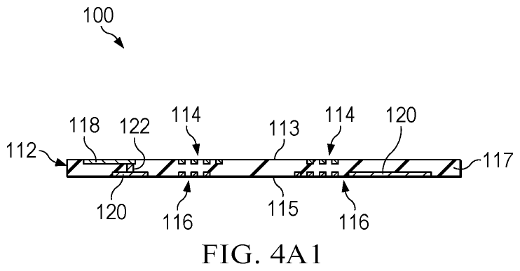

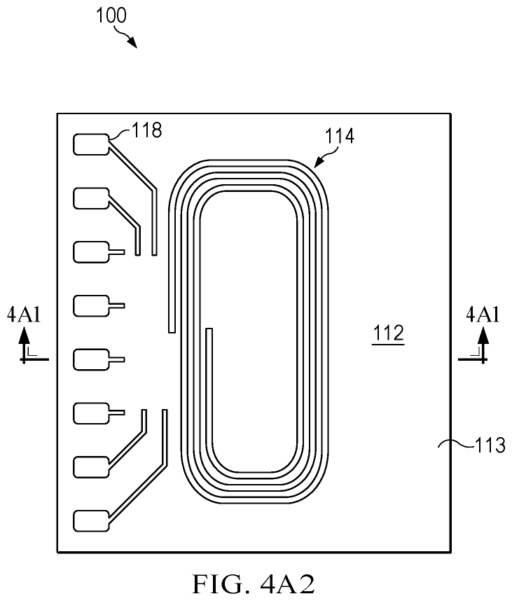

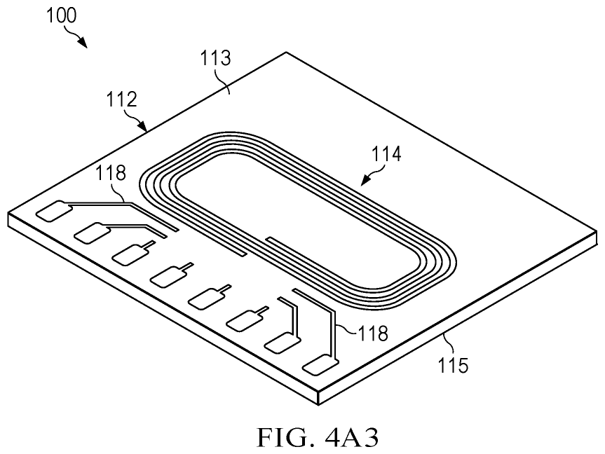

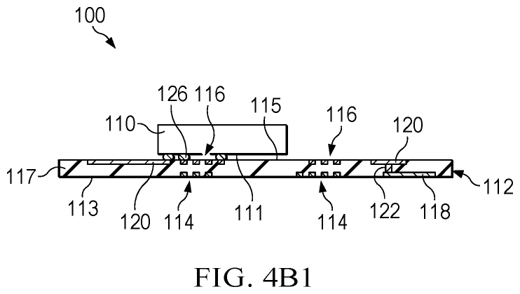

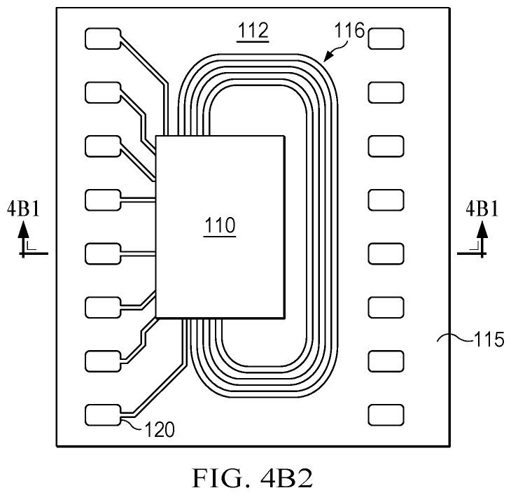

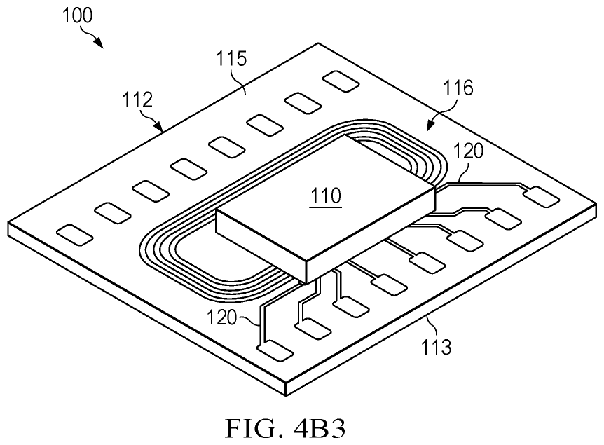

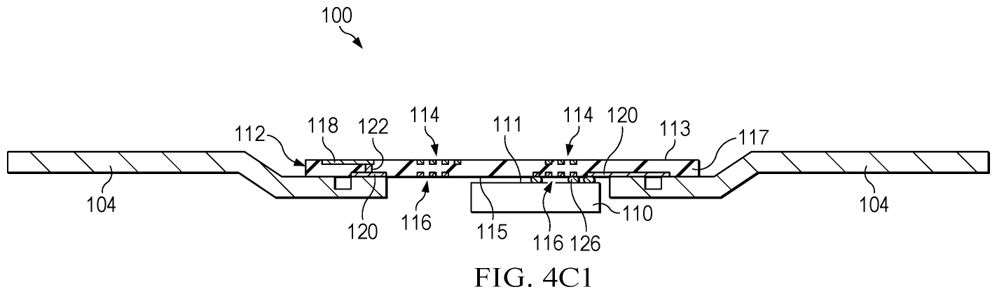

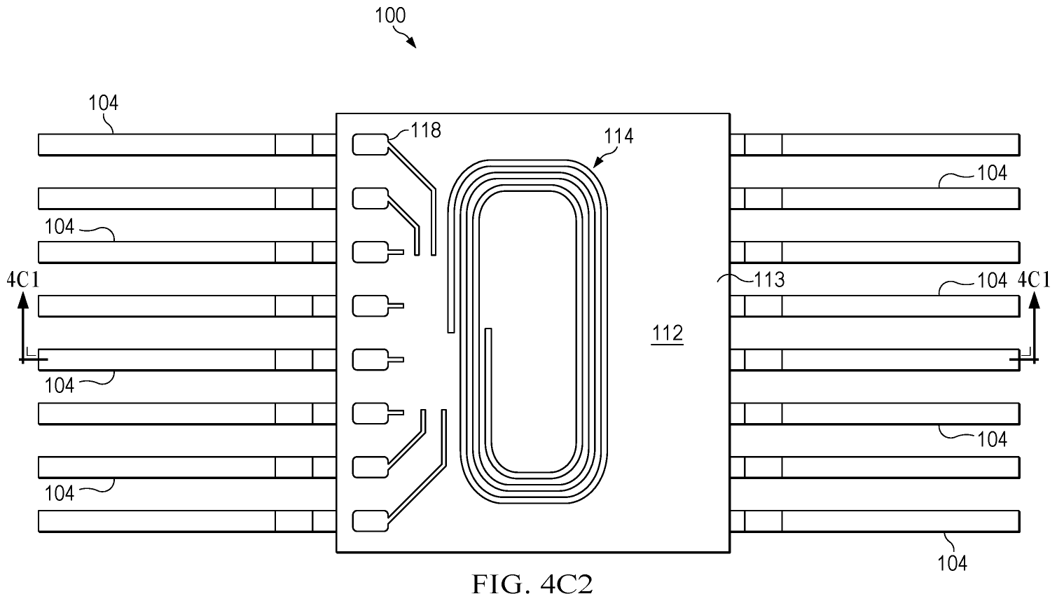

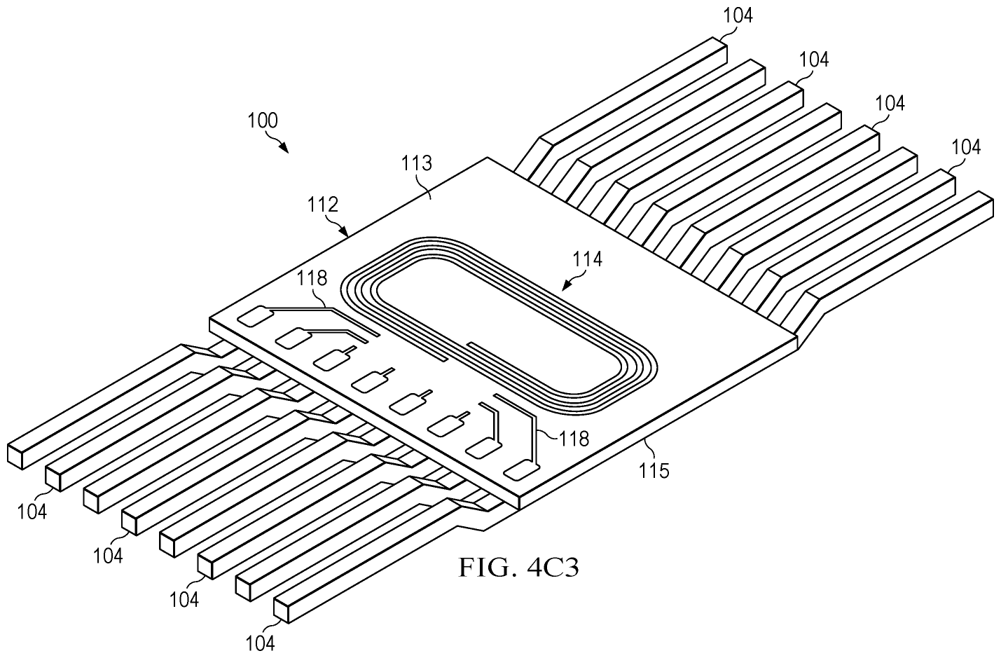

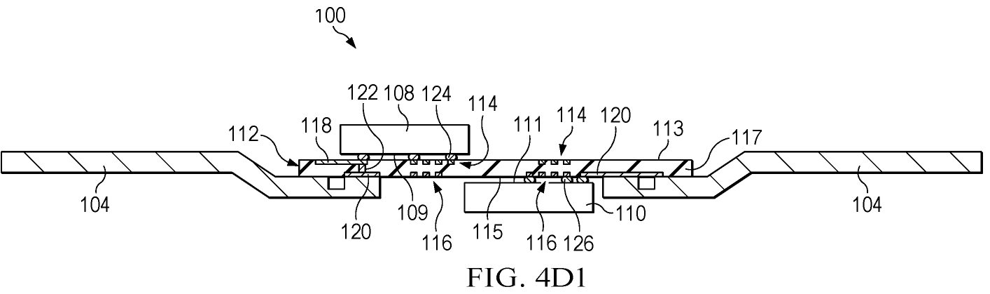

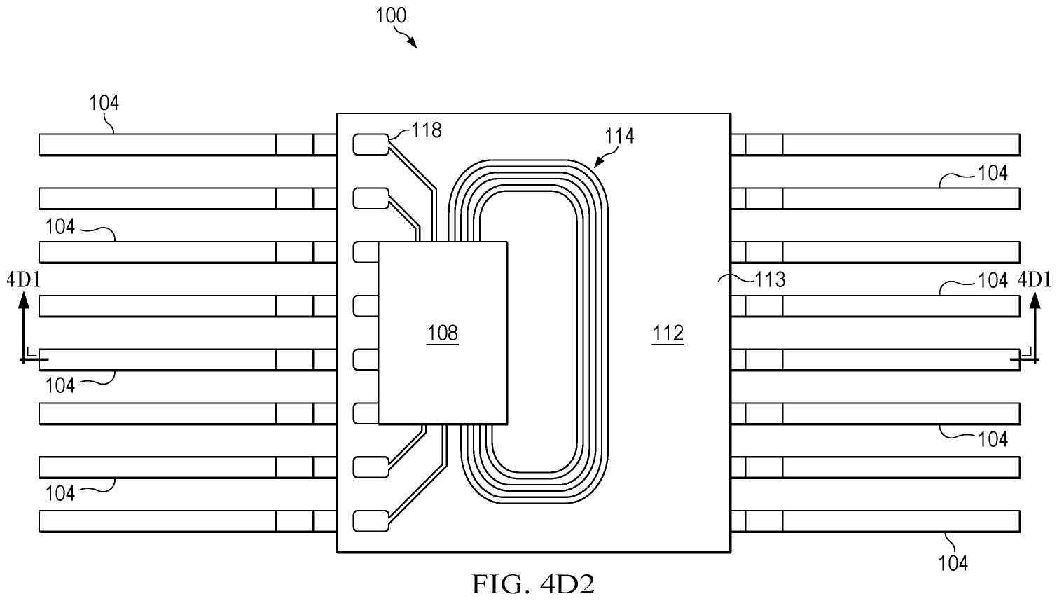

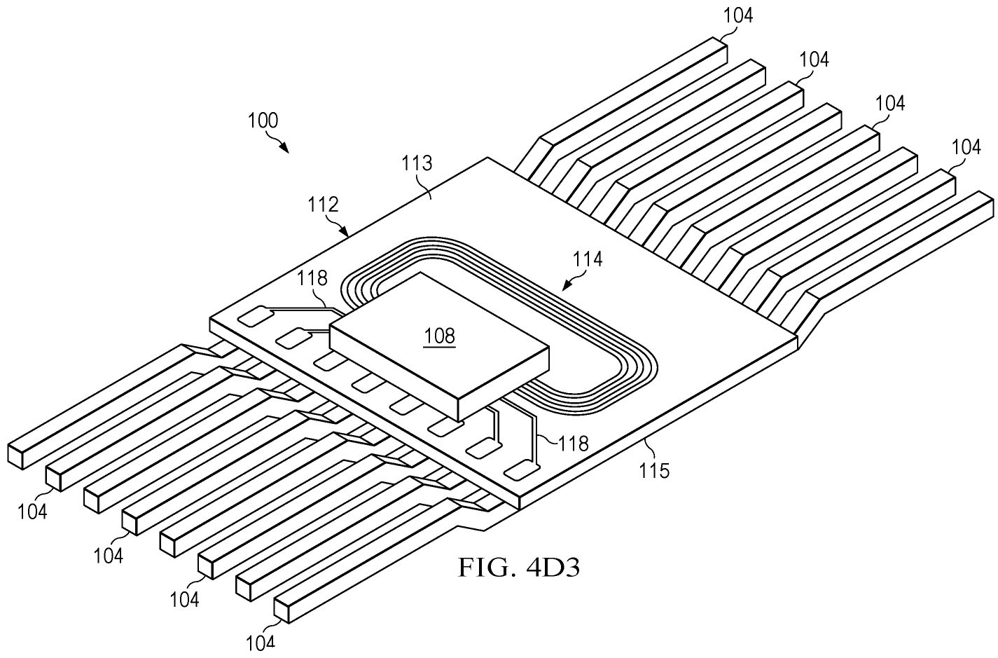

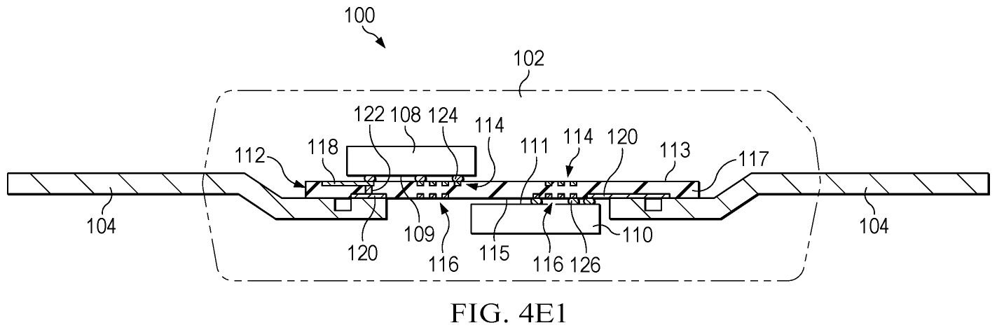

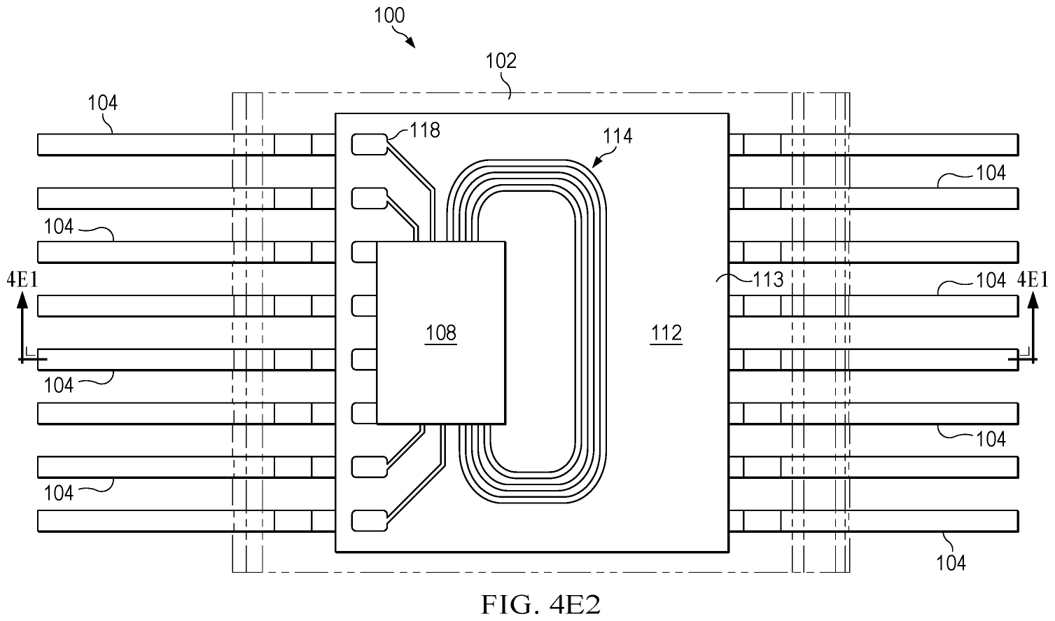

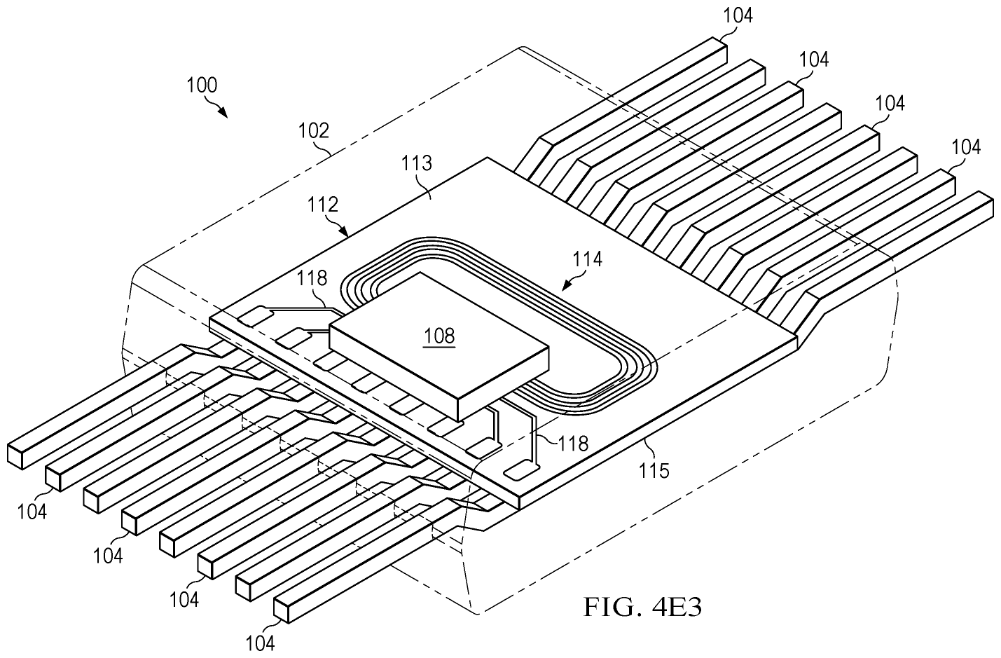

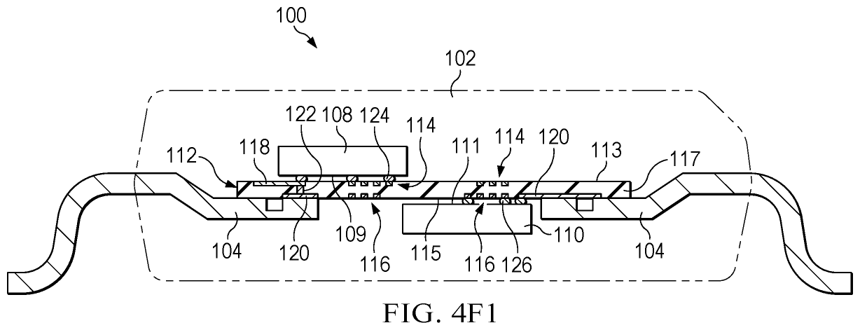

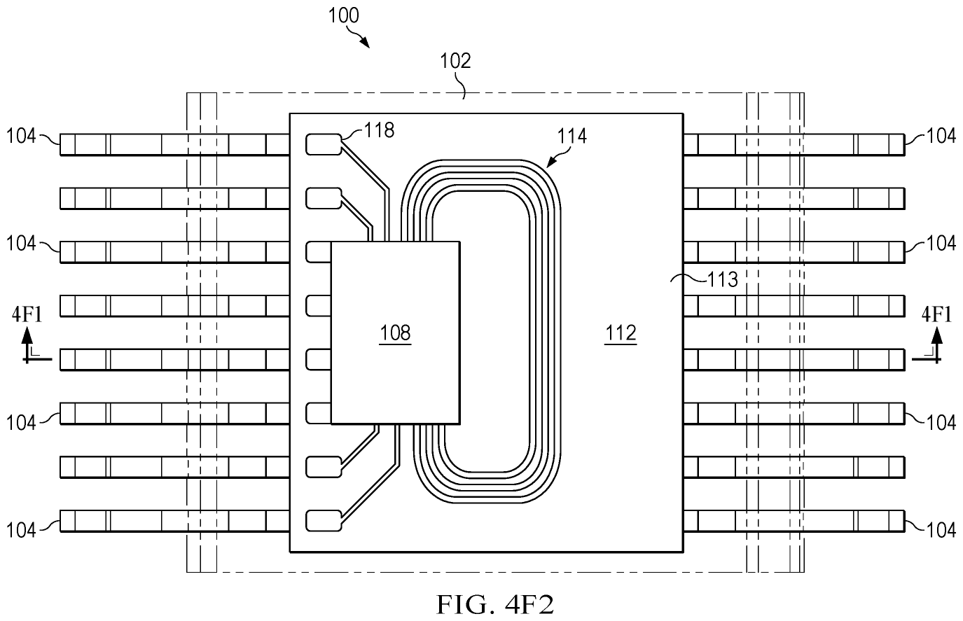

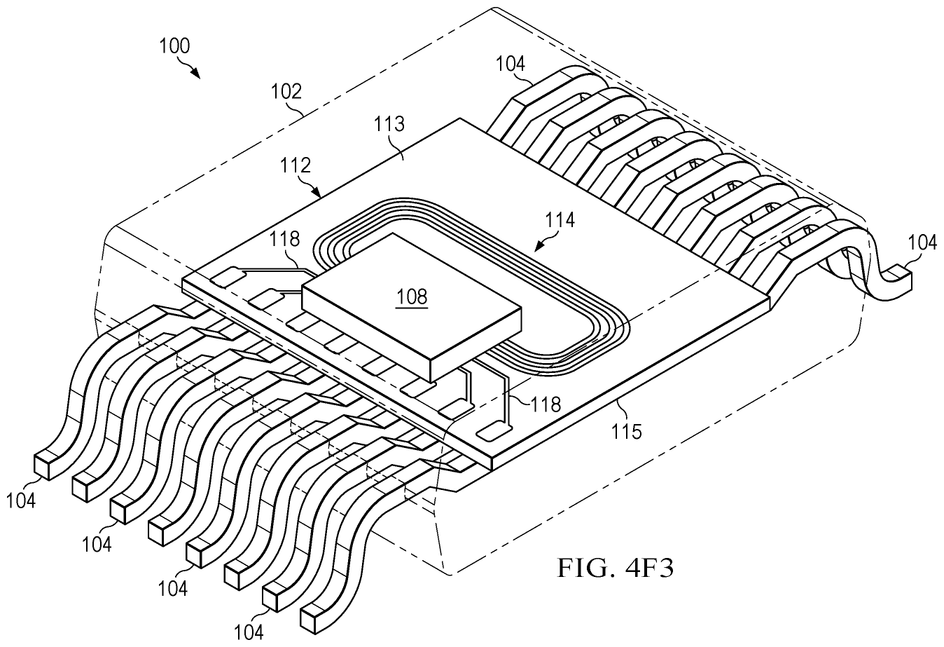

FIG. 3 is a flow diagram of a method 300 for manufacturing an isolation device (e.g., an isolation device 100) in accordance with various examples. FIGS. 4A1-4F3 are a process flow for manufacturing an isolation device in accordance with various examples. Accordingly, FIGS. 3 and 4A1-4F3 are now described in parallel.

The method 300 includes forming a substrate, such as the substrate 112, through an iterative plating (e.g., electroplating) and dielectric film deposition process (302). FIG. 4A1 is a profile, cross-sectional view of the substrate 112 having been formed through an iterative process of electroplating and dielectric film deposition. For example, in a first step, a seed layer may be deposited on a metal carrier, and photolithographic processes may be used to plate some or all of a first coil (e.g., the coil 116) and first traces co-planar with the first coil (e.g., the traces 120). In a second step, dielectric film may be deposited (e.g., by way of lamination) on and around the first coil and the first traces. In a third step, the dielectric film and electroplated metal may be grinded. These steps may be repeated until the first coil and first traces are fully formed. Subsequently, one or more layers of dielectric film may be deposited, followed by another iterative process in which electroplating, photolithography, and grinding are used to form a second coil (e.g., the coil 114) and second traces co-planar with the second coil (e.g., the traces 118). This iterative process is continued until the second coil and second traces are fully formed, and adequate dielectric film has been deposited to surround and contact the second coil and second traces (e.g., until the multi-layer substrate 112 of FIG. 1A or 2A has been fully formed). FIG. 4A2 is a top-down view of the structure of FIG. 4A1, in accordance with various examples. FIG. 4A3 is a perspective view of the structure of FIG. 4A1, in accordance with various examples.

The method 300 includes coupling a bottom die to a bottom surface of the substrate by solder reflow (304). FIG. 4B1 is a profile, cross-sectional view of the structure of FIG. 4A1, except with the addition of the semiconductor die 110 coupled to the surface 115 of the substrate 112 by solder bumps 126. Specifically, the device side 111 of the semiconductor die 110 is coupled to the coil 116 and metal traces 120 by way of the solder bumps 126, as shown. FIG. 4B2 is a top-down view of the structure of FIG. 4B1, in accordance with various examples. FIG. 4B3 is a perspective view of the structure of FIG. 4B1, in accordance with various examples.

The method 300 includes coupling the substrate to a lead frame strip by solder reflow, with the bottom semiconductor die facing downward toward the lead frame conductive terminals (306). FIG. 4C1 is a profile, cross-sectional view of the structure of FIG. 4B1, except that the structure of FIG. 4B1 has been coupled to conductive terminals 104 of a lead frame strip. As shown, the conductive terminals 104 are flat, not bent as in FIG. 1A, as the conductive terminals 104 are still coupled to the lead frame strip. FIG. 4C2 is a top-down view of the structure of FIG. 4C1, in accordance with various examples. FIG. 4C3 is a perspective view of the structure of FIG. 4C1, in accordance with various examples.

The method 300 includes coupling a top die to a top surface of the substrate by solder reflow (308). FIG. 4D1 is a profile, cross-sectional view of the structure of FIG. 4C1, except that the semiconductor die 108 has been coupled to the surface 113 of the substrate 112 by way of solder bumps 124. FIG. 4D2 is a top-down view of the structure of FIG. 4D1, in accordance with various examples. FIG. 4D3 is a perspective view of the structure of FIG. 4D1, in accordance with various examples.

The method 300 includes applying a mold compound to the structures of FIG. 4D1 (310). FIG. 4E1 is a profile, cross-sectional view of the structure of FIG. 4D1, except that the mold compound 102 has been applied to cover the various structures of FIG. 4D1, as shown. Any suitable technique may be useful to apply the mold compound 102, such as injection molding. FIG. 4E2 is a top-down view of the structure of FIG. 4E1, in accordance with various examples. FIG. 4E3 is a perspective view of the structure of FIG. 4E1, in accordance with various examples.

The method 300 includes trimming the leads from the lead frame and bending the leads (312). FIG. 4F1 is a profile, cross-sectional view of the structure of FIG. 4E1, except that the conductive terminals 104 have been trimmed so as to detach from a lead frame strip, and the conductive terminals 104 are subsequently bent to have a gullwing (or other suitable) shape. FIG. 4F2 is a top-down view of the structure of FIG. 4F1, in accordance with various examples. FIG. 4F3 is a perspective view of the structure of FIG. 4F1, in accordance with various examples.

The scope of this disclosure is not limited to the precise manufacturing process flow shown in FIGS. 4A1-4F3. For example, solder paste may be stencil printed onto a substrate 112, and the substrate 112 may be coupled to the top surfaces of the leads of a lead frame (e.g., by reflowing the solder paste that was stencil printed onto the substrate 112). A semiconductor die (e.g., semiconductor die 110) may be coupled to the bottom surface of the substrate 112 (i.e., the surface of the substrate 112 facing the leads). Another semiconductor die (e.g., semiconductor die 108) may be coupled to the top surface of the substrate 112 (i.e., the surface of the substrate 112 facing away from the leads). A mold compound may then be applied to cover the dies 108, 110, the substrate 112, the leads, and other components of the package.

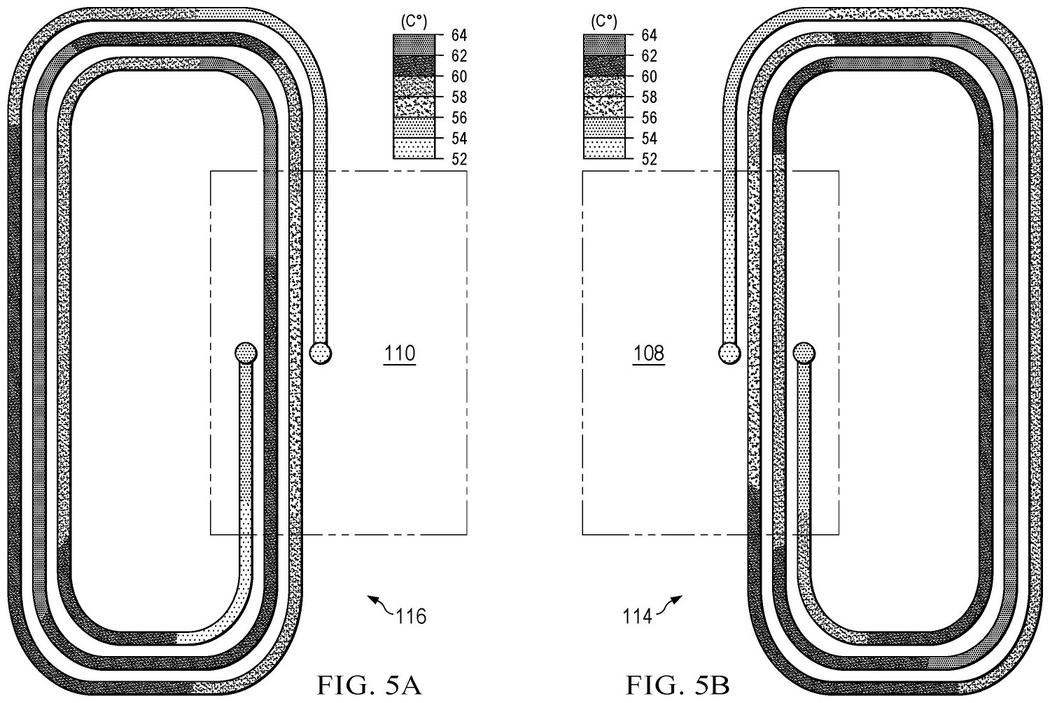

As described above, an advantage to coupling semiconductor dies 108, 110 on opposing surfaces 113, 115 of the substrate 112 is increased heat dissipation from the coils 114, 116. Efficient heat dissipation is particularly valuable in power applications, such as in the isolation device 100, where significant amounts of heat are generated. Positioning the semiconductor die 108 directly above the coil 114, as shown in FIGS. 1A-1C and 2A-2C, encourages heat dissipation from the coil 114 and through the semiconductor die 108. Similarly, positioning the semiconductor die 110 directly below the coil 116, as shown in FIGS. 1A-1C and 2A-2C, encourages heat dissipation from the coil 116 and through the semiconductor die 110. FIGS. 5A and 5B are top-down views of isolation device substrate coils 116 and 114, respectively, indicating temperatures across the coils in accordance with various examples. As FIG. 5A shows, relative to the remainder of the coil 116, the portion of the coil 116 that is in vertical alignment with the semiconductor die 110 is cooler due to heat dissipation from the coil 116 and through the semiconductor die 110. Similarly, as FIG. 5B shows, relative to the remainder of the coil 114, the portion of the coil 114 that is in vertical alignment with the semiconductor die 108 is cooler due to heat dissipation from the coil 114 and through the semiconductor die 108.

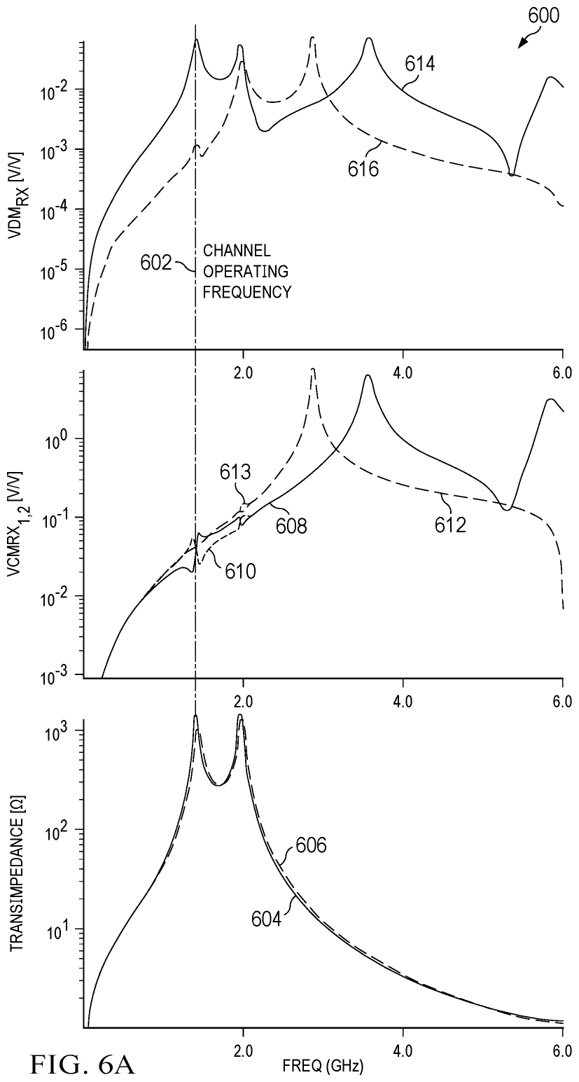

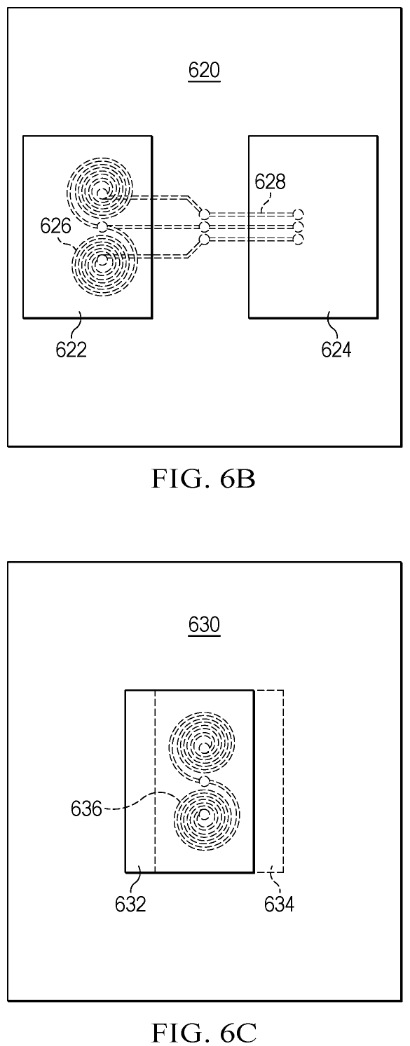

FIG. 6A is a graph 600 depicting operational behavior of isolation devices, in accordance with various examples. The graph 600 includes three sub-graphs. The three sub-graphs share a common x-axis, which indicates frequency in gigahertz (GHz). The y-axes for the top two sub-graphs indicate voltage gain in V/V, and the y-axis for the bottom sub-graph indicates transimpedance in ohms. Numeral 602 indicates an example channel operating frequency for an example isolation device (e.g., isolation device 100). The third (i.e., bottom-most) sub-graph illustrates transimpedance, describing the behavior of the communication channel of an example isolation device operating as a double-tuned transformer. A differential current is provided to the example isolation device resonating at a given frequency (e.g., as indicated on the x-axis), and the voltage response magnitude is determined at the output of the isolation device (e.g., as indicated on the y-axis). Curve 604 indicates the performance typical of a traditional isolation device in which the semiconductor dies are located on the same surface of the substrate. FIG. 6B depicts such a traditional isolation device having a substrate 620, dies 622 and 624 on the same surface of the substrate 620, coils 626 in vertical alignment with each other, and connectors 628 connecting the die 624 to one of the coils 626. The connectors 628 distort the capacitive and inductive differential symmetry of the isolation device, leading to the poorer performance demonstrated in the graph 600, as described below. Curve 606 indicates the performance of an isolation device in accordance with examples herein (i.e., in which the semiconductor dies are located on opposing surfaces of a multi-layer substrate). FIG. 6C depicts such an example isolation device, which includes a substrate 630, dies 632 and 634 on opposing surfaces of the substrate 630, and coils 636 in vertical alignment with each other positioned inside the substrate 630. The example isolation device of FIG. 6C omits the connectors 628 that would otherwise result in the capacitive and inductive differential asymmetry described above, thus improving performance, as described below. As shown by curves 604 and 606, the behavior of the isolation devices of FIGS. 6B and 6C in terms of transimpedance does not vary significantly.

The second (i.e., middle) sub-graph illustrates the common mode voltage transfer function seen across the halves of the receiving transformer coil (i.e., from one end of the coil to the center tap, and from the opposite end of the coil to the center tap) for the frequency sweep depicted on the x-axis. The curves 608, 610 depict the voltage response for the common mode voltages typical of traditional isolation devices (e.g., such as the isolation device of FIG. 6B), while curves 612, 613 depict the voltage response for the common mode voltages of an example isolation device (e.g., isolation device 100, or the isolation device of FIG. 6C). As shown, the curves 608, 610 depict the operational asymmetry that exists in traditional isolation devices (e.g., the isolation device of FIG. 6B), as depicted by the incongruity near the channel operating frequency 602 and the congruity that exists at the remaining frequencies of the x-axis. This asymmetry results in the operational disadvantages described above. In contrast, the curves 608, 610 depict the operational symmetry of example isolation devices (e.g., the isolation device 100, or the isolation device of FIG. 6C), across the full range of frequencies depicted on the x-axis, including the channel operating frequency 602. This operational symmetry results in the mitigation of the technical disadvantages associated with inductive asymmetry as described above.

The first (i.e., top-most) sub-graph represents the differential between the common mode voltages (i.e., the voltage across the receiving coil). At the channel operating frequency 602, the curve 616 (which depicts the behavior in an example isolation device, such as isolation device 100, or the isolation device of FIG. 6C) has a substantially lower (e.g., 60 times lower on the log scale graph 600) voltage than does the curve 614 (which depicts the behavior typical of a traditional isolation device, such as in FIG. 6B), thus confirming the symmetry depicted by curves 612, 613 as compared to the asymmetry depicted by curves 608, 610. The virtually eliminated operational asymmetry in example isolation devices (e.g., isolation device 100) mitigates the above-described challenges associated with inductive asymmetry, and further inoculates the performance of example isolation devices (e.g., isolation device 100) against external disturbances by reducing the common mode to differential mode conversion that asymmetry would provide. For example, in a symmetric system, external disturbances are not reflected in the differential between common mode voltages and thus do not affect the operational integrity of the example isolation devices (e.g., isolation device 100, or the isolation device of FIG. 6C).

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A. Other types of coupling, such as inductive, capacitive, and optical coupling, are also contemplated and included in the scope of this disclosure.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Uses of the term “ground” and variations thereof in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. An isolation device, comprising:
a multi-level substrate having opposing first and second surfaces, the multi-level substrate including:
a first coil in a first layer of the substrate, the first coil having first and second terminals;
a second coil in a second layer of the substrate that is vertically distanced from the first layer, the second coil having third and fourth terminals; and
a dielectric material covering the first and second coils;
a first semiconductor die coupled to the first surface and to the first and second terminals;
a second semiconductor die coupled to the second surface and to the third and fourth terminals, the second semiconductor die galvanically isolated from the first semiconductor die;
conductive terminals coupled to the multi-level substrate; and
a mold compound covering the multi-level substrate, the first and second semiconductor dies, and the conductive terminals.

2. The device of claim 1, wherein the dielectric material comprises a build-up film.

3. The device of claim 1, wherein the conductive terminals are coupled to the second surface.

4. The device of claim 1, wherein the conductive terminals are coupled to the first surface.

5. The device of claim 1, wherein a vertical line orthogonal to the first and second surfaces extends through both the first and second semiconductor dies.

6. The device of claim 1, wherein no vertical line that is orthogonal to the first and second surfaces extends through both the first and second semiconductor dies.

7. The device of claim 1, wherein the first layer is between the first surface and the second layer.

8. The device of claim 1, wherein the second layer is between the second surface and the first layer.

9. The device of claim 1, wherein the dielectric material is a solid dielectric material and not air.

10. The device of claim 1, wherein the first and second coils form a transformer.

11. The device of claim 1, wherein the first and second semiconductor dies are coupled to the first, second, third, and fourth terminals by solder bumps.

12. The device of claim 1, wherein device sides of the first and second semiconductor dies in which circuitry is formed face the substrate.

13. An isolation device, comprising:
a multi-level substrate having opposing first and second surfaces, the multi-level substrate including:
a first coil in a first layer of the substrate that is closer to the first surface than to the second surface, the first coil having first and second terminals;
a second coil in a second layer of the substrate that is closer to the second surface than to the first surface, the second coil having third and fourth terminals; and
a dielectric material covering the first and second coils;
a first semiconductor die coupled to the first and second terminals with a first set of solder bumps;
a second semiconductor die coupled to the third and fourth terminals with a second set of solder bumps, the first and second semiconductor dies separated from each other by a first distance in the vertical direction and by a second distance in the horizontal direction;
conductive terminals coupled to the multi-level substrate; and
a mold compound covering the multi-level substrate, the first and second semiconductor dies, and the conductive terminals, the conductive terminals exposed to an exterior of the mold compound.

14. The device of claim 13, wherein the dielectric material comprises a build-up film.

15. The device of claim 13, wherein the substrate is not a printed circuit board (PCB) and the dielectric material is not air.

16. The device of claim 13, wherein device sides of the first and second semiconductor dies in which circuitry is formed face the substrate.

17. A method for manufacturing an isolation device, comprising:
coupling a first semiconductor die to a first coil of a multi-layer substrate using first solder bumps, the substrate including a second coil and a dielectric material covering the first and second coils;
coupling the substrate to conductive terminals of a lead frame;
coupling a second semiconductor die to the second coil using second solder bumps, the first and second semiconductor dies coupled to opposing surfaces of the substrate;
covering the substrate and the first and second semiconductor dies with a mold compound; and
trimming the conductive terminals to detach the conductive terminals from the lead frame.

18. The method of claim 17, wherein device sides of the first and second semiconductor dies in which circuitry is formed face the substrate.

19. The method of claim 17, wherein the power module package lacks bond wires.

20. The method of claim 17, wherein the first and second coils form a transformer.

21. The method of claim 17, wherein the dielectric material is a build-up film.

22. The method of claim 21, wherein the dielectric material is not air, and wherein the substrate is not a printed circuit board (PCB).

23. An isolation package, comprising:
a substrate having first and second coupling members and first and second surfaces, the first and second surfaces opposing each other;
a first semiconductor die coupled to the first surface and to the first coupling member;
a second semiconductor die coupled to the second surface and to the second coupling member, the second semiconductor die galvanically isolated from the first semiconductor die;
conductive terminals coupled to the substrate; and
a mold compound covering the substrate, the first and second semiconductor dies, and the conductive terminals.

24. The package of claim 23, wherein the first and second coupling members are inductive coupling members.

25. The package of claim 23, wherein the first and second coupling members are capacitive coupling members.

26. The package of claim 23, wherein the first and second coupling members are optical coupling members.

27. The package of claim 23, wherein the conductive terminals are package leads.
